(19) United States
(12) Patent Application Publication
(10) Pub. No.: US 2010/0315869 A1
(43) Pub. Date: Dec. 16, 2010

(54) Spin torque transfer MRAM design with low switching current

(75) Inventors: Tai Min, San Jose, CA (US); Witold Kula, Sunnyvale, CA (US)

Correspondence Address: SAILE ACKERMAN LLC, 28 DAVIS AVENUE, POUGHKEEPSIE, NY, 12603, US

(73) Assignee: MagIC Technologies, Inc.

(21) Appl. No.: 12/456,324

(22) Filed: Jun. 15, 2009

(51) Int. Cl. G11C 11/14; H01L 21/00; H01L 29/82

(52) U.S. Cl. 365/171; 438/3; 257/421; 257/E21.001; 257/E29.323

(57) ABSTRACT

The invention discloses a method to store digital information through use of spin torque transfer in a device that has a very low critical current. This is achieved by adding a spin filtering layer whose direction of magnetization is fixed to be parallel to the device's pinned layer.

### FIELD OF THE INVENTION

The invention relates to the general field of Magnetic Random Access memory (MRAM) more particularly to devices in which switching is achieved through spin torque transfer that occurs when current through a given memory cell exceeds some critical value.

### BACKGROUND OF THE INVENTION

Magnetic tunneling junctions (MTJ) and giant magneto-resistance (GMR) Spin Valves (SV) comprise two ferromagnetic layers separated by a non-magnetic layer. In MTJs this is a tunneling oxide layer while in GMR-SVs it is a good metallic conductor layer. They have been widely studied for use as memory elements in magnetic random access memories (MRAM). Usually the magnetization of one of the ferromagnetic layers is in a fixed direction (i.e. it is a pinned layer), while the other layer is free to switch its magnetization direction, and is usually called the free layer.

For MRAM applications, the storage of the digital information is encoded as the direction of magnetization of the free layer with minimum or maximum resistances corresponding to the free layer magnetization being parallel or anti-parallel to the pinned layer magnetization respectively. The mechanism that keeps the free layer magnetization parallel or anti-parallel to the reference layer is usually shape anisotropy which occurs whenever the shape is other than circular, such as an ellipse. In the quiescent state, the free layer magnetization 11 lies along the long axis of the cell (see FIG. 1) and is in the direction of magnetization of pinned layer 13 (FIG. 2), either parallel or anti-parallel thereto. This long axis is referred to as the easy axis (x), the direction perpendicular to it being the hard axis (y). In FIG. 2, layer 12 represents a transition layer which is metal for GMR and insulating for MTJ.

One way to achieve switching of the free layer magnetization is by using the spin torque transfer (STT) switching mode, as described in refs. [1] and [2] and also in U.S. Pat. No. 6,130,814. When a device is responsive to STT, the free layer magnetization gets switched by sending a current (above some critical value Ic) through the MTJ or SV cell. The direction of this switching current determines whether the free layer magnetization becomes parallel (P) or anti-parallel(AP) to the reference layer.

To switch the free layer from AP to P, the electrons need to flow from the pinned layer into the free layer. After passing through the pinned layer, most of the electrons will have their spins in the same direction as the pinned layer. The free layer's magnetization is opposite to that of the pinned layer so after transiting the spin neutral non-magnetic spacer, the majority of electron spins will be opposite to that of the free layer and thus will interact with the magnetization moment of the free layer near the interface between the free layer and the non-magnetic spacer. Through this interaction, the spin of electrons can be transferred to the free layer. When the current is higher than the critical value Ic, the magnetization of the free layer can be switched to the P state through sufficient spin momentum transfer by electrons.

To switch from P to AP, the electrons need to flow in the opposite direction, i.e. from the free layer to the pinned layer. After transiting the free layer, the majority of electrons will have their spins in the same direction of magnetization as that of the free and the pinned layers. They can therefore pass through the pinned layer with minimal scattering. The minority electrons (i.e. those with the opposite spin) get reflected back to the free layer, transferring their spin to the free layer. Once the number of reflected minority electrons (spin polarized so as to oppose the free layer magnetization) is sufficient, the magnetization of the free layer will be switched to the AP state.

In practical applications for high density memory, the critical current Ic cannot be very high since it is provided by a transistor connected to the MTJ and it is this transistor's size that determines the density of the memory. Also, MTJs with a dielectric spacer such as MgO are the preferred choice since they provide high Dr/r (up to 600%) which is critical for memory read signal strength and speed. To avoid exceeding the dielectric breakdown voltage of the MTJ, a low critical current density (Jc) is essential for the MRAM design.

Numerous efforts have been made trying to reduce the critical current Ic/current density Jc. Jc is proportional to:

∝α/PMₛt(H_{eff}−2πMₛ) [Ref. 2]

where α is the Gilbert damping constant, P is the spin transfer efficiency, Mₛ is the magnetization of the free layer, t is the free layer thickness, and H_{eff} is the effective field including the external magnetic field, the shape anisotropy field, the exchange field between the free layer and pinned layers, and the dipole field from the pinned layer.

One approach to reducing Jc in a MTJ (disclosed in U.S. Pat. Nos. 6,714,444 and 7,241,631) [and featuring a MgO/Free/AlOx structure] is to add a second pinned layer separated from free layer by a second spacer made of either non-magnetic metal or an insulator. The magnetization direction of this second pinned layer is set to be opposite to the 1^{st} pinned layer. This enables both free layer-to-non-magnetic spacer interfaces to contribute to driving the spin torques [Ref. 3].

Switching from AP to P. After transiting the free layer the spin of a majority of electrons will be polarized to be in the direction of the free layer magnetic moment and the second pinned layer. The minority electrons will be scattered back to the free layer by the second pinned layer, generating additional spin torque to switch the free layer magnetization to the P state.

Switching from P to AP. The electrons will be polarized by the magnetization of the second pinned layer, which is the opposite of the free layer, and transfer their spin torque to the free layer in addition to the spin torque transferred by the minority electrons reflected by the first pinned layer, as described above. Both spacers of this design are non-magnetic, either metal or oxide. However, if the second spacer is metal, the damping constant, α, can experience a significant, and detrimental, increase due to spin pumping (see Ref. [4]) at the interfaces with the free layer and the second metal spacer.

Increasing damping constant α will increase Jc, as described before. Also, the free layer, the second spacer and the second pinned layer effectively form another MTJ or SV whose dr/r is in the opposite direction, thereby undesirably reducing the net read signal. This reduction of dr/r is most detrimental if the second spacer is a tunneling insulator. To minimize the negative contribution to dr/r of the second tunneling insulator the latter has to have a much smaller resistance.area product than the 1^{st} tunneling insulator. However, when writing into the MTJ with spin torque transfer, the total resistance.area product of the MTJ has to be small in order to avoid dielectric breakdown. However, giving the second tunneling insulator such a low resistance.area product is very difficult as well as being prone to dielectric breakdown.

U.S. Pat. No. 7,057,921 B2 [featuring a spacer/Free/NCC structure (see more below on NCC)] discloses an attempt to solve the high damping constant difficulty discussed above. A reduction of the damping constant α is effected by suppressing the spin pumping contribution coming from the outer surface of the free layer. This is achieved by introducing a spin barrier layer between the free layer and the second pinned layer. The spin barrier layer is made of a non-magnetic insulating oxide or nitride with high resistance.area product or their matrix with current confining channels. The current confining channels are made of non-magnetic metals or areas with low oxygen concentration (<30%).

U.S. Pat. No. 7,242,048 B2, [pinned/NCC/pinned] teaches a design that utilizes the ballistic magneto-resistance (BMR) effect by replacing the 1^{st} spacer with a magnetic current confined layer made of an insulating matrix in which is embedded at least one magnetic channel to connect the free layer to the 1^{st} pinned layer. The magnetic channel has to serve as a magnetic point contact between the free layer and the pinned layer and it needs to be sufficiently small (less than the electron coherence length) for BMR effects to occur [Ref. 5].

A second pinned layer, with a non-magnetic spacer between it and the free layer, has to be added in order to write the free layer from the P to the AP state by reflecting the minority electrons back to the free layer. Such a structure is, however, very difficult to manufacture because of the level of control of the size, uniformity and impurity concentration of these magnetic contacts within the insulating matrix that is required. A further difficulty is that any change in temperature or magnetic state can affect many other factors such as magnetically induced stress relief, magnetostriction, dipole-dipole interactions to induce compression, and expansion of the magnetic point contacts all of which can greatly affect the resistance and magneto-resistance of this type of junction.

Ref. [6], teaches using a composite free layer in the MTJ as schematically illustrated in FIGS. 3a-3c. This composite free layer is made up of nano-current-channel (NCC) layer 32 sandwiched between ferromagnetic layers 31 and 33. Also shown in FIG. 3a are barrier layer 34, pinned layer 35, and antiferromagnetic layer 36. The NCC layer is illustrated in greater detail in FIG. 3b, which shows multiple columns 39, each made up of magnetic grains 37, within insulator matrix 38.

The magnetic NCC grains 37 are exchange coupled at each of their ends to the two ferromagnetic layers 31 and 33. The result is that they act as a single free layer as illustrated in FIG. 3c which shows the magnetization to be uniform throughout the structure. During writing, however, the spin current that passes through the MTJ will be able to flow only through the conducting magnetic grains of the NCC layer. This results in a local high current density that leads to magnetization switching of the NCC grains. Since, as just noted, the latter are exchange coupled to the two ferromagnetic layers, magnetization switching of the entire structure readily occurs. In this way the critical current density may be reduced by factor of 2.8, as reported in Ref. [6]. A paper by Wang et al. (Ref. [7]) is to be credited for being the first to demonstrate the utility of a SiO₂—Fe matrix NCC.

### REFERENCES

[1] J. C. Slonczewski, “Current-driven excitation of magnetic multilayers”, J. Magn.Magn.Mater., vol. 159, pp. L1-L7, 1996
[2] J. Sun, “Spin-current interaction with a monodomain magnetic body: A model study”, Phys. Rev. B 62, 570 (2000)
[3] L. Berger, “Multilayer configuration for experiments of spin precession induced by a dc current”, JAP 93(2003) 7693
[4] Y. Tserkovnyak et. al. “Dynamic stiffness of spin valves”, Phys. Rev. B 67, 140404 (2003)
[5] A. R. Rocha, et. al. “Search for magneto-resistance in excess of 1000% in Ni point contacts: Density functional calculations”, Phys. Rev. B, 76 054435 (2007)
[6] H. Meng, et. al. “Composite free layer for high density magnetic random access memory with lower spin transfer current”, Appl. Phys. Left. 89 (2006), 152509
[7] J. Wang, et. al. “Composite media (dynamic tilted media) for magnetic recording”, Appl. Phys. Lett. 86, 142504 (2005)

A routine search of the prior art was performed with the following additional references of interest being found:

In U.S. 2008/0180991, Wang discloses an NCC layer in a composite free layer. Huai, in U.S. 2006/0192237, describes a current-confined layer between the pinned and free layers, including nano-conductive channels. U.S. 2007/0164336 (Saito et al) shows a free layer with a ferromagnetic nano-structure and a ferroelectric nano-structure. U.S. Pat. No. 7,161,829 (Huai et al) teach a magnetic current confined layer between the pinned and free layers comprising nano-conductive channels and, in U.S. 2008/0251867, Wunnicke discloses an MRAM with a columnar nano-structure.

### SUMMARY OF THE INVENTION

It has been an object of at least one embodiment of the present invention to provide a method for storing information by means of spin torque transfer induced by an electric current that is passed through a magnetic device.

Another object of at least one embodiment of the present invention has been that the critical current through said magnetic device, above which spin torque transfer occurs, be lower than that found in similar devices currently available.

Still another object of at least one embodiment of the present invention has been to provide a method for manufacturing said magnetic device.

A further object of at least one embodiment of the present invention has been to provide design parameters for optimizing the performance of said magnetic device.

These objects have been achieved by providing a STT based MRAM design whose critical switching current has been reduced to be less than that of any of the known earlier designs. This has been achieved through the addition of a spin filtering layer (SFL) to the device as well as by including a nano-current channel (NCC) whose function is to confine the current flowing through the device locally, thereby maximizing the current density through its part of the free layer.

Thus, above the critical current, STT induced magnetization switching takes effect inside the NCC first but the resulting magnetization is soon exchange transferred to the rest of the free layer which is a conventional ferromagnetic layer (FML). If the coupling strength between the NCC and FML layers is too large the existing magnetization of the FML could interfere with the STT effectiveness within the NCC so it becomes critical for this coupling to not be too strong. A suitable value is about 200 Oe or less. The SFL is formulated so that its magnetization cannot be switched by the spin current that would be used to store data in the device. It has a preferred direction of magnetization that is opposite to the magnetization direction of the pinned layer.

### BRIEF DESCRIPTION OF THE DRAWINGS

FIG. 1 illustrates the elliptical shape commonly used for the free layer.

FIG. 2 schematically shows the key elements in a GMR or MTJ device.

FIG. 3a is schematic drawing of a composite free layer comprising a nano-current-channel sandwiched between ferromagnetic layers

FIG. 3b is an isometric close-up view a nano-current-channel

FIG. 3c is a cross-sectional view two ferromagnetic layers connected by a nano-current-channel.

FIG. 4 is a cross-sectional view of the structure of the present invention.

FIG. 5a illustrates the directions of magnetization of the various layers for the parallel state.

FIG. 5b illustrates the directions of magnetization of the various layers for the antiparallel state.

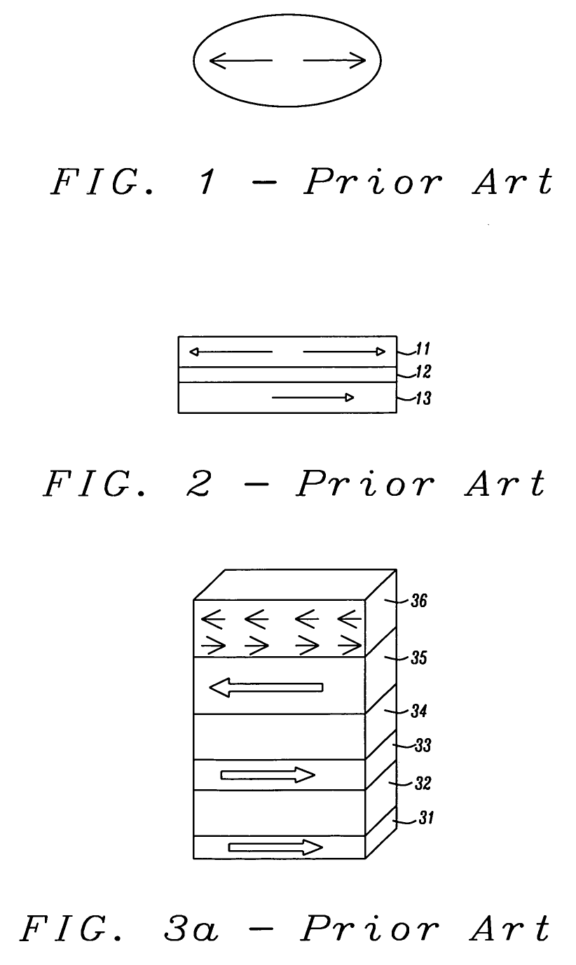

### DESCRIPTION OF THE PREFERRED EMBODIMENTS

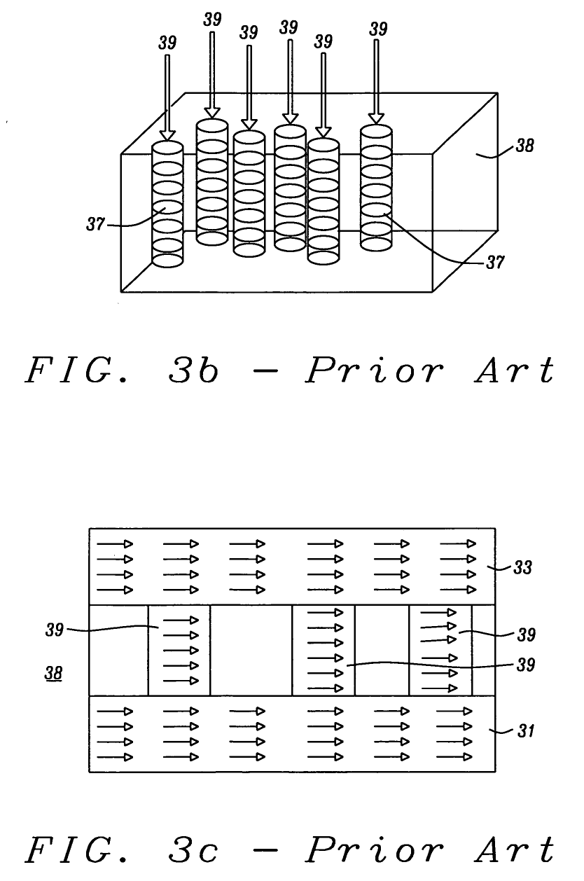

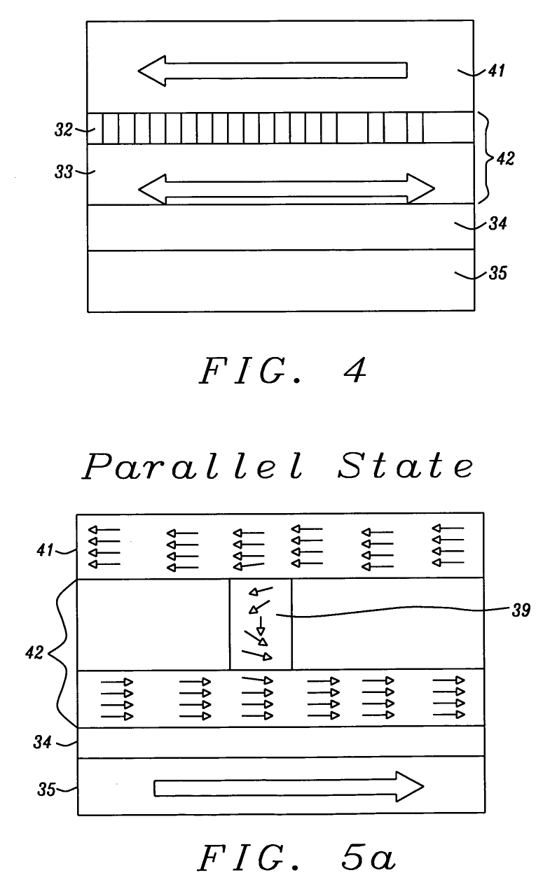

The invention discloses a STT based MRAM design whose critical switching current has been reduced to be less than that of any of the earlier designs described above. This has been achieved through use of the structure shown in FIG. 4. In part this structure is similar to FIG. 3c (order of layers inverted) and includes NCC layer 32, ferromagnetic layer (FML) 33, insulating spacer layer 34, and pinned layer 35. Anti-ferromagnetic layer 36 is also part of the invented structure but is not shown in FIG. 4.

If the FML is too strongly coupled with the NCC, switching of the latter through STT could be compromised so it is an important feature of the invention that it is critical for the coupling strength between NCC 32 and FML 33 to be less than about 40 Oe. Conversely, if the coupling is too weak (less than about 3.6 Oe), switching the NCC may have no effect on the FML.

Achieving an optimum coupling strength between NCC 32 and FML 33 was accomplished by adjusting the composition and thickness of the NCC, by controlling the FML thickness and composition and through use of optimum sputtering conditions. Composition-wise the NCC can be Co, Fe, or Ni, in any combination mixed with a dielectric insulator whose concentration in the mix is low enough for the mix to still be electrically conductive, and for the NCC grains to remain ferromagnetic.

Generally speaking, as long as the total amount of Co, Fe, and CoFe is in the range from 10-40 atomic %, the NCC layer will function well.

The thickness of the individual NCC grains can be from 2 Å to 100 Å, for example as Fe—SiO2, with from 3-50 Å being preferred. For the full NCC containing layer, we have found thickness values in the range of from 4-15 Å to function satisfactorily with thicknesses in the range of from 5-12 Å being optimum. In practice, there is usually a tradeoff to be made between the metal composition and the NCC thickness when optimizing performance of a given NCC structure. Such optimization tradeoffs have been found to vary significantly from one material system to another.

The insulator matrix surrounding the NCC can be an oxide of material such as Al, Mg, Si, Ge, B, Zr, Ti, V, Ta, Mo, W, or Nb or a nitride of a material such as Al, B, Li, C, Si, Ge, or Ti.

Briefly stated, the process for forming the NCC layer is RF sputtering of a Fe(SiO₂)₃ target under deposition conditions, including thickness, that are optimized for obtaining the desired R.A product, exchange coupling level, and uniformity of conduction through the NCC.

An important novel feature of the invention is spin-filtering layer (SFL) 41 that replaces ferromagnetic layer 31 (as seen FIG. 3a). Consequently, free layer 42 consists only of layers 32 and 33, there being no layer 31 involvement (as in the prior art structures). Unlike layer 31, the SFL is formulated so that its magnetization cannot be switched by the spin current under normal operating conditions. In general the critical current for switching the SFL will exceed the current required for switching the FMUNCC by about 60%.

Additionally, the SFL has a preferred direction of magnetization that is opposite to the magnetization direction of pinned layer 35. Typical compositions for the SFL include (but are not limited to) Co, Fe or their alloys doped with a third element such as B, C, or P. An example is: CoₓFe₁₋ₓ with x ranging from about 10 to 80 and having a thickness in the range of about 20 to 100 Angstroms. The thickness of the SFL is not critical as long as it thicker than the minimum thickness that is needed to effectively reflect most of the minority electrons while continuing to be pinned by the second antiferromagnetic layer.

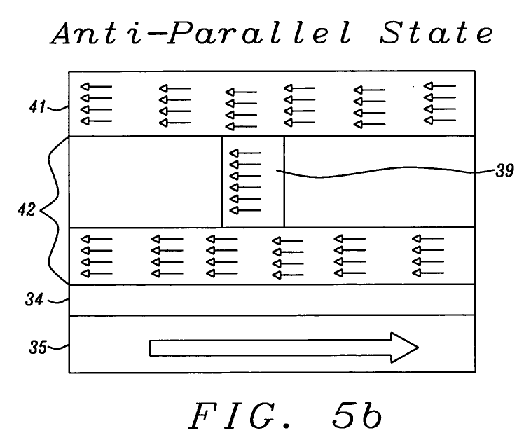

Thus, the structure can be in one of two states, depending on whether free layer 42 is parallel to pinned layer 35 (FIG. 5a) or antiparallel (FIG. 5b). In both cases the SFL remains antiparallel to the pinned layer. Note that in the P state (FIG. 5a), a domain wall may be present inside of, but not limited to, one or more of the NCC grains.

Switching Mechanisms Under Which the Invention Operates:

When switching from the P to the AP state, the electrons flow from SFL towards pinned layer. In addition to the switching spin torque that arises from minority electrons reflected by the pinned layer at its interfaces with the ferromagnetic layer and spacer (including the current that was confined inside the NCC), there is an additional switching force due to the presence of the SFL. After passing through the SFL, a majority of electrons will be polarized by its magnetization (which is opposite to that of the pinned layer and also (in this case) that of the FML. The electrons confined to flow within the NCC grains will transfer their spins to the domain walls inside the NCC grains (FIG. 5a) through domain wall scattering, either unwinding it or pushing it into the ferromagnetic layer, thereby providing an additional force to switch the FML magnetization into its AP state.

When switching from the AP to the P state, the current that was polarized by the pinned layer transfers spin torque to the FML, the presence of the NCC serving to confine the current to the magnetic grains thereby increasing the local current density. Now, the majority of electrons from the FML when attempting to enter the SFL have spins opposite thereto making them minority electrons relative to the SFL. This causes them to be reflected back into the NCC and the FML and provides an additional driving spin torque to switch the magnetization of the magnetic grains of the NCC and the FML, leading to a further reduction of the critical switching current required by this design relative to the conventional NCC designs of the prior art.

Design Choices for SFLs:

There are several preferred embodiments for the SFL. In the first embodiment, the SFL is a relatively thick (20 Å to 100 Å) ferromagnetic layer of Co, Fe, or Ni, including their alloys, which may, optionally, be doped with elements such as B, C, Pt, Pd Cr, W, Hf, Mo, Zr, Nb, Ta, Rh, Ru or rare earth elements at concentrations that result in a Jc value that is an order of magnitude higher than that of the FML.

This increase in the SFL's Jc value is due to its greater thickness which requires a much higher STT switching current than the STT switching current of the FML. So, in practice, the magnetization of the SFL remains unchanged during write operation of the STT cells. The reason for doping the SFL with a third element is to increase the anisotropy field and the damping constant of the SFL to prevent STT induced switching.

For writing data, the spin current is adjusted to fall in a range that is higher than the Ic of the free layer but much lower than that of the SFL. The direction of magnetization of the SFL can be set to be opposite to that of the pinned layer by exposure to an external magnetic field whose strength exceeds the SFL's own shape anisotropy field.

For the second preferred embodiment, a material is selected for the SFL whose crystalline anisotropy field Hk exceeds about 300 Oe. Below this value, an MTJ (with dimensions 0.1×0.2 microns and a thickness of about 20 Angstroms) cannot be relied on to be thermally stable. Possible materials include Co, Ni, or Fe as well as their alloys, optionally doped with elements such as B, C, Pt, Pd Cr, W, Hf, Mo, Zr, Nb, Ta, Rh, Ru. The magnetization direction can be set by an external field to be opposite to that of the pinned layer.

In the third preferred embodiment, the SFL is in permanent contact with a layer of antiferromagnetic material, which serves to pin the magnetization of the SFL in a direction that is opposite to that of the pinned layer.

Note that in any or all of the embodiments mentioned above, the pinned layer, the FML and SFL can be replaced by a pair of ferromagnetic layers antiferromagnetically coupled through a non-magnetic material such as Ru, Rh, Cr, Cu, or Re.

What is claimed is:

1. A method to store digital information, comprising:
forming a magnetically pinned layer on a substrate;
depositing a tunneling barrier layer on said magnetically pinned layer;
depositing a ferromagnetic layer (FML) on said tunneling barrier layer;
forming a nano-current-channel (NCC) containing layer on said FML, said FML and NCC together constituting a free layer that is subject to spin torque transfer (STT) by an electrical current whose value equals or exceeds a first critical value Ic1;
magnetizing said magnetically pinned layer in a first direction;
forming a spin-filtering layer (SFL) on said NCC, said SFL being responsive to STT by an electrical current whose value equals or exceeds a second critical value Ic2 that exceeds Ic1 by a factor of at least 5;
magnetizing said SFL in a fixed direction that is antiparallel to said first direction, thereby forming a memory element;
then passing through said memory element an electric current of value between Ic1 and Ic2 in a direction that causes electrons to flow from said SFL towards said magnetically pinned layer whereby said SFL remains magnetized in said fixed direction while, through STT, said free layer is magnetized in a direction that is antiparallel to said first direction thereby storing a first bit of information in said memory element; and
passing through said memory element an electric current of value between Ic1 and Ic2, in a direction that causes electrons to flow from said magnetically pinned layer towards said SFL, whereby said SFL remains magnetized in said fixed direction while, through STT, said free layer is magnetized in a direction that is parallel to said first direction thereby storing in said memory element a bit of information that is logically inverted relative to said first bit.

2. The method of claim 1 further comprising adjusting said FML and NCC's composition and thickness so that coupling strength between said SFL layer and said FML is between 1 and 200 Oe.

3. The method of claim 1 further comprising forming said spin-filtering-layer from materials whose crystalline anisotropy field equals or exceeds 300 Oe.

4. The method of claim 1 wherein said SFL contains one or more elements selected from the group consisting of B, C, Pt, Pd Cr, W, Hf, Mo, Zr, Nb, Ta, Rh, Ru, and all rare earth elements.

5. The method of claim 1 wherein said SFL comprises Co, Fe or CoₓFe₁₋ₓ where x ranges from 10 to 90, wherein the SFL remains ferromagnetic and wherein the SFL does not switch during a MRAM cell write operation.

6. The method of claim 1 wherein said SFL is deposited to a thickness between about 20 and 100 Angstroms.

7. The method of claim 1 further comprising depositing on said SFL a layer of anti-ferromagnetic material which serves to pin the magnetization of said SFL in said fixed direction.

8. The method of claim 1 wherein said SFL further comprises a pair of ferromagnetic layers antiferromagnetically coupled through a non-magnetic material selected from the group consisting of Ru, Rh, Cr, Cu, and Re.

9. The method of claim 1 wherein individual grains that constitute a column in said NCC layer, each have a thickness that is between about 3 and 50 Angstroms and a diameter between about 3 and 50 Angstroms.

10. The method of claim 1 wherein said NCC containing layer is deposited to an overall thickness of between about 3 and 50 Angstroms.

11. A device for storing digital information, comprising:
a magnetically pinned layer on a substrate;
a tunneling barrier layer on said magnetically pinned layer;
a ferromagnetic layer (FML) on said tunneling barrier layer;
a nano-current-channel (NCC) containing layer on said FML, said FML and NCC together constituting a free layer that is subject to spin torque transfer (STT) by an electrical current whose value equals or exceeds a first critical value I_{c1};
said magnetically pinned layer being magnetized in a first direction;
a spin-filtering layer (SFL) on said NCC layer, said SFL being responsive to STT by an electrical current whose value equals or exceeds a second critical value I_{c2} that exceeds I_{c1} by a factor of at least 5;
said SFL being magnetized in a direction that is antiparallel to said first direction;
said magnetically pinned layer, said tunneling barrier layer, said free layer, and said SFL together constituting a memory element wherein an electric current of value between I_{c1} and I_{c2}, that causes electrons to flow from said SFL towards said magnetically pinned layer, would store a first bit of information in said memory element; and
wherein an electric current of value between I_{c1} and I_{c2}, that causes electrons to flow from said magnetically pinned layer towards said SFL, would store, in said memory element, a bit of information that is logically inverted relative to said first bit.

12. The device described in claim 11 wherein said FML and NCC's composition, thickness has been adjusted so that coupling strength between said SFL and said FML is between 1 and 200 Oe.

13. The device described in claim 11 wherein said spin-filtering-layer is formed from materials whose crystalline anisotropic field equals or exceeds 300 Oe.

14. The device described in claim 11 wherein said SFL contains one or more elements selected from the group consisting of Co, Fe, Ni and their alloys with optional addition of B, C, Pt, Pd, Cr, W, Hf, Mo, Zr, Nb, Ta, Rh, Ru and all rare earth elements.

15. The device described in claim 11 wherein said SFL comprises Co, Fe or CoₓFe₁₋ₓ where x ranges from 10 to 90.

16. The device described in claim 11 wherein said SFL has a thickness between about 3 and 50 Angstroms.

17. The device described in claim 11 further comprising a layer of anti-ferromagnetic material that is in contact with said SFL whereby said SFL's magnetization is pinned in a direction that is opposite to that of said pinned layer.

18. The device described in claim 11 wherein said SFL further comprises a pair of ferromagnetic layers antiferromagnetically coupled to each other through a non-magnetic material selected from the group consisting of Ru, Rh, Cr, Cu, and Re.

19. The device described in claim 11 wherein individual grains that collectively form a column in said NCC layer, each have a thickness that is between about 3 and 50 Angstroms.

20. The device described in claim 10 wherein said NCC containing layer has an overall thickness in a range of from 3 to 50 Angstroms.
